(19) United States
(12) Patent Application Publication
(10) Pub. No.: US 2024/0244755 A1
(43) Pub. Date: Jul. 18, 2024

(54) Metal Foil for Circuit Board, Metal Foil with Carrier, Copper-Clad Laminate and Printed Circuit Board

(71) Applicant: Guangzhou Fangbang Electronics Co., Ltd, Guangzhou, Guangdong (CN)

(72) Inventors: Qiang GAO, Guangzhou City, Guangdong (CN); Yuhua ZHU, Guangzhou City, Guangdong (CN); Meijuan ZHANG, Guangzhou City, Guangdong (CN); Ke ZHANG, Guangzhou City, Guangdong (CN); Weiping JIANG, Guangzhou City, Guangdong (CN); Kaihui ZHU, Guangzhou City, Guangdong (CN); Zhi SU, Guangzhou City, Guangdong (CN)

(21) Appl. No.: 18/559,749

(22) PCT Filed: May 30, 2022
(86) PCT No.: PCT/CN2022/095933

§ 371 Date: Nov. 8, 2023

(30) Foreign Application Priority Data
Jun. 8, 2021 (CN) 202110634320.2

(51) Int. Cl. H05K 1/18; H05K 3/02

(52) U.S. Cl. CPC H05K 1/188; H05K 3/022; H05K 2201/09054; H05K 2203/0264

(57) ABSTRACT

The disclosure discloses a metal foil, a metal foil with a carrier, a copper-clad laminate and a Printed Circuit Board. Herein, a plurality of protrusions are distributed on one face of the metal foil, and the protrusions have the follow microscopic morphology: the lower half part of the protrusion connected with the one face of the metal foil is provided with a limiting part, and the diameter of a circumscribed circle of the cross section of the limiting part is smaller than the skin depth of the metal foil; and the surface area of the part of the protrusion above the limiting part is larger than the surface area of other parts of the protrusion.

### CROSS-REFERENCE TO RELATED APPLICATION

The present disclosure claims the priority of Chinese Patent Application No. 202110634320.2, filed to the China National Intellectual Property Administration on Jun. 8, 2021 and entitled “metal foil, metal foil with carrier, copper-clad laminate and Printed Circuit Board”, which is incorporated herein its entirety by reference.

### TECHNICAL FIELD

The disclosure relates to the technical field of materials, and in particular to a metal foil, a metal foil with a carrier, a copper-clad laminate and a Printed Circuit Board (PCB).

### BACKGROUND

PCBs are widely used in electronic devices. With the continuous improvement of the functions of semiconductor electronic components, the integration level and data transmission speed of electronic components in an electronic device are getting higher and higher. Thus, the density of signal transmission lines on a PCB as a signal transmission carrier is getting higher and higher, which enables the signal transmission lines to be thinner and thinner, and the frequency of signal current in the signal transmission lines to get higher and higher. Therefore, the transmission effect of high-frequency signals has become one of the standards to measure the performance of the PCB. Herein, the structure of the PCB consists of metal foils and a dielectric layer adhering between the metal foils. After being etched, the metal foil forms a signal transmission line for signal transmission, and the dielectric layer mainly plays an insulating role. The metal foil is generally a copper foil layer, and the dielectric layer is generally a resin layer. The signal transmission line formed by etching the metal foil is bonded to the resin layer through the surface of the line.

The physical mechanism of signal transmission loss in the PCB includes conductor loss due to the metal foil of the PCB and dielectric loss due to the dielectric layer. Herein, for the dielectric loss due to the dielectric layer, the dielectric loss of the dielectric layer may be reduced to an ideal degree by selecting a resin layer of a special material. Therefore, the conductor loss of the metal foil becomes a major factor of the signal transmission loss of the PCB. One of the most important characteristics of conductor loss is that the electromagnetic skin effect increases with the increase of signal frequency. The intrinsic reason thereof is that the high-frequency signal current flows in a thinner surface layer of the metal surface of the transmission line. Herein, the higher the signal frequency is, the smaller the depth of current flowing in the signal transmission line of the metal foil is. There are a large number of literatures to study the relationship between signal loss of circuit board transmission line and metal surface roughness. For example, the article “Signal Transmission Loss due to Copper Surface Roughness in High-Frequency Region” introduces the signal loss caused by copper foil surface roughness, which points out that: the lower the surface roughness of a copper foil is, the lower the signal loss is. Therefore, the transmission of high-frequency signals requires that the roughness of the metal surface be as low as possible. However, with the increasing integration of the PCB, the signal transmission line formed on the copper foil layer of the PCB is thinner and thinner, and the bonding area between the signal transmission line of the copper foil and the dielectric layer is smaller, which leads to smaller bonding force between the signal transmission line of the copper foil and the dielectric layer, and thus it is easier to fall off in layers. The bonding force between the copper foil layer and the dielectric layer is another important factor that affects the performance of the PCB. The reason is that the signal transmission line of the copper foil layer is attached to the resin layer through the surface roughness to produce binding force with the dielectric layer. As the signal transmission line becomes thinner and thinner, about this aspect, the article “Non-Classical Conductor Losses due to Copper Foil Roughness and Treatment” points out that: the adhesion between the copper foil and the dielectric layer is related to the roughness of the copper foil. The greater the roughness of the copper foil is, the greater the adhesion between the copper foil and the dielectric layer of the PCB is, and accordingly the higher the peeling strength between the copper foil and the dielectric layer is. Therefore, the trend of fine signal transmission lines caused by the high integration of the PCB requires that the surface roughness of the copper foil be increased to some extent so as to ensure the bonding force with the dielectric layer.

Generally speaking, on the one hand, in order to reduce the transmission loss of high-frequency signals, a conventional art requires that the roughness of the metal foil be as small as possible. On the other hand, the development trend of high-density fine line of the PCB requires that the roughness of the metal foil be as large as possible. That is, the two requirements of the conventional art on the surface morphology of the metal foil are mutually contradictory, and the high-frequency signal transmission loss of the metal foil and the peeling strength between the high-density signal transmission line on the metal foil and the dielectric layer cannot be considered at the same time.

### SUMMARY

At least one purpose of embodiments of the disclosure is to provide a metal foil, a meta foil with a carrier, a copper-clad laminate and a Printed Circuit Board (PCB), which can not only reduce the high-frequency signal transmission loss of the metal foil, but also enable a signal transmission line formed by manufacture of the metal foil and a dielectric layer to have good peeling strength so that both are not easy to fall off in layers. Thus, the manufacture of a high-density and fine-line high-frequency circuit board with the metal foil can be implemented.

In order to solve the above technical problem, the embodiments of the disclosure provide a metal foil. A plurality of protrusions are distributed on one face of the metal foil, and the protrusions have the following microscopic morphology:

a lower half part of the protrusion connected with the one face of the metal foil is provided with a limiting part, and a diameter of a circumscribed circle of a cross section of the limiting part is smaller than a skin depth of the metal foil; and a surface area of the part of the protrusion above the limiting part is larger than a surface area of other parts of the protrusion.

As an improvement of the abovementioned solution, the skin depth δ is equal to: δ=\sqrt{1/(π*f*σ*μ)}, wherein σ is a conductivity of the material of the protrusion, f is a signal frequency in a case that the metal foil is used as a signal transmission carrier, and μ is the magnetic permeability.

As an improvement of the abovementioned solution, a height of the limiting part relative to the one face of the metal foil is not more than 2 microns, and a height of the protrusion relative to the one face of the metal foil is not more than 3 microns.

As an improvement of the abovementioned solution, a ratio of a longitudinal length of the part of the protrusion above the limiting part to a height of the protrusion is: 1/2-5/6.

As an improvement of the abovementioned solution, a shape of the protrusion is tree-shaped, hung-ice-shaped or water-drop-shaped.

As an improvement of the abovementioned solution, the protrusion comprises a trunk part and a branch part. The trunk part extending outward from the one face, the trunk part is provided with the limiting part, and the branch part extending outward from a surface of a part of the trunk part above the limiting part.

As an improvement of the abovementioned solution, a material composition of the trunk part is the same as that of the metal foil.

As an improvement of the abovementioned solution, a material composition of the trunk part is different from that of the metal foil, and the material of the trunk part is selected from at least one of copper, nickel, zinc, chromium, aluminum, silicon, alumina particles and industrial diamond particles.

As an improvement of the abovementioned solution, on the one face, at least 10% of the protrusions have the microscopic morphology.

As an improvement of the abovementioned solution, on the one face, at least 50% of the protrusions have the microscopic morphology.

As an improvement of the abovementioned solution, on the one face, at least 90% of the protrusions have the microscopic morphology.

As an improvement of the abovementioned solution, the signal frequency f is 1 Hz-100 GHz.

As an improvement of the abovementioned solution, the metal foil includes a copper foil and/or an aluminum foil.

As an improvement of the abovementioned solution, the metal foil is a single-layer metal structure or a multi-layer metal structure composed of at least two single metal layers.

Another embodiment of the disclosure provides a metal foil with a carrier, which may include a carrier layer and a metal foil described in any of the abovementioned solutions. The carrier layer is arranged on another face, opposite to the one face, of the metal foil in a peelable manner.

As an improvement of the abovementioned solution, the metal foil with the carrier may also comprises a peeling layer. The peeling layer is located between the carrier layer and the metal foil, so that both the metal foil and the carrier layer are arranged in a peelable manner.

As an improvement of the abovementioned solution, the metal foil with the carrier may also include a first adhesive layer, and the first adhesive layer is arranged between the carrier layer and the peeling layer.

As an improvement of the abovementioned solution, the first adhesive layer is a metal adhesive layer. The metal adhesive layer is made of any one or more materials of copper, zinc, nickel, iron and manganese or, the metal adhesive layer is made of one of copper and zinc and one of nickel, iron and manganese.

As an improvement of the abovementioned solution, the metal foil with a carrier may also include a first anti-oxidation layer, and the first anti-oxidation layer is arranged on the face of the metal foil close to the carrier layer.

As an improvement of the abovementioned solution, the material of the first anti-oxidation layer is at least one of nickel, copper alloy and chromium.

As an improvement of the abovementioned solution, the metal foil with a carrier may also include a second anti-oxidation layer, and the second anti-oxidation layer is arranged on the face of the metal foil away from the carrier layer.

As an improvement of the abovementioned solution, the material of the second anti-oxidation layer is at least one of nickel, chromium and zinc.

Another embodiment of the disclosure provides a copper-clad laminate, which is obtained using the metal foil described in any of the abovementioned solutions or the metal foil with a carrier described in any of the abovementioned solutions.

As an improvement of the abovementioned solution, the copper-clad laminate further includes a dielectric layer, and the dielectric layer is arranged on the one face of at least one metal foil.

As an improvement of the abovementioned solution, the material of the dielectric layer is selected from at least one of polyimide (for example thermoplastic polyimide), modified epoxy resin, modified acrylic resin, polyethylene terephthalate, polybutylene terephthalate, polyethylene, polyethylene naphthalate, polystyrene, polyvinyl chloride, polysulfone, polyphenylene sulfide, polyetheretherketone, polyphenylene ether, polytetrafluoroethylene, liquid crystal polymer, polyparabanic acid, epoxy glass cloth and BT resin.

As an improvement of the abovementioned solution, the copper-clad laminate further includes a second adhesive layer, and the second adhesive layer is arranged on the one face of the metal foil.

As an improvement of the abovementioned solution, the material of the second adhesive layer is selected from at least one of polystyrene, vinyl acetate, polyester, polyethylene, polyamide, rubber or acrylate thermoplastic resin, phenolic, epoxy, thermoplastic polyimide, carbamate, melamine or alkyd thermosetting resin, BT resin and ABF resin.

Another embodiment of the disclosure provides a PCB, which is obtained using the metal foil described in any of the abovementioned solutions, the metal foil with a carrier described in any of the abovementioned solutions, or the copper-clad laminate described in any of the abovementioned solutions.

Compared with the conventional art, the metal foil, the metal foil with a carrier, the copper-clad laminate, the PCB and a manufacturing method of the metal foil provided by the embodiments of the disclosure have at least one of the following beneficial effects.

Since a plurality of bumps are distributed on one face of the metal foil, and the bumps have the follow microscopic morphology: the lower half part of the bump connected with the one face is provided with a limiting part, and the diameter of a circumscribed circle of the cross section of the limiting part is smaller than the skin depth of the metal foil; and the surface area of the part of the bump above the limiting part is larger than the surface area of other parts of the bump. Thus, when the metal foil is manufactured to form a signal transmission line, the limiting part of the bump has large impedance, and the narrower the limiting part of the bump is, the larger the impedance of the bump is. Since the diameter of the circumscribed circle of the cross section of the limiting part of the lower half part of the bump is smaller than the skin depth, it is difficult for the high-frequency signal current in the metal foil to pass through the limiting part of the bump as limited by the limiting part of the lower half part of the bump. Thus, the high-frequency signal current flowing to the bump is reduced, enabling the high-frequency signal loss of the signal transmission line formed by manufacture of the metal foil of the embodiments of the disclosure to be less affected by the bump on the surface of the metal foil, and reducing the high-frequency signal transmission loss of the signal transmission line formed by manufacture of the metal foil. Furthermore, since the surface area of the part of the bump above the limiting part is larger than the surface area of other parts of the bump, the surface area of the part of the bump above the limiting part is larger than the surface area of the part of the bump above the limiting part, so that the bump has a relatively large surface area, and thus the signal transmission line formed by manufacture of the metal foil has a large contact area with the dielectric layer. Further, the signal transmission signal and the dielectric layer have good peeling strength, so that both are not easy to fall off in layers, and the high-density and fine-line high-frequency circuit board can be manufactured using the metal foil.

### BRIEF DESCRIPTION OF THE DRAWINGS

FIG. 1 is a schematic diagram of a longitudinal section of a metal foil according to an embodiment of the disclosure.

FIG. 2 shows an overall structure of a protrusion in FIG. 1.

FIG. 3 is a schematic diagram showing the flow of high-frequency signal current on a metal foil when the width of the lower part of a protrusion in the metal foil is greater than the skin depth.

FIG. 4 is a schematic diagram showing the flow of high-frequency signal current on a metal foil when the minimum width of the lower part of a protrusion of the metal foil is less than the skin depth according to an embodiment of the disclosure.

FIG. 5 is a schematic structural diagram of a metal foil according to an embodiment of the disclosure.

FIG. 6 is an electron microscope view of a metal foil provided with a plurality of protrusions on one face according to an embodiment of the disclosure.

FIG. 7 is an electron microscope view of a metal foil provided with a plurality of protrusions on one face according to another embodiment of the disclosure.

FIG. 8 is an electron microscopic view of a conventional metal foil.

FIG. 9 is a scanning curve diagram of protrusion slices of a metal foil and a conventional metal foil according to an embodiment of the disclosure.

FIG. 10 is a logarithmic spectrum diagram of corresponding spatial Fourier transform of a curve in FIG. 9.

FIG. 11 is a schematic structural diagram of a pressing assembly used in the process of testing the peeling strength between the face, provided with a protrusion, of a metal foil and a resin layer according to an embodiment of the disclosure.

FIG. 12 is a schematic structural diagram of a metal foil with a carrier according to an embodiment of the disclosure.

FIG. 13 is a schematic structural diagram of a metal foil with a carrier according to another embodiment of the disclosure.

FIG. 14 is a schematic structural diagram of a metal foil with a carrier according to yet another embodiment of the disclosure.

FIG. 15 is a schematic structural diagram of a metal foil with a carrier according to yet another embodiment of the disclosure.

FIG. 16 is a schematic structural diagram of a metal foil with a carrier according to yet another embodiment of the disclosure.

FIG. 17 is a schematic structural diagram of a copper-clad laminate according to an embodiment of the disclosure.

FIG. 18 is a schematic structural diagram of a copper-clad laminate according to another embodiment of the disclosure.

FIG. 19 is a schematic structural diagram of a copper-clad laminate according to yet another embodiment of the disclosure.

Description of drawings: 1. Metal foil; 2. Protrusion; 20. Trunk part; 21. Branch part; 3. Carrier layer; 4. Peeling layer; 5. First anti-oxidation layer; 6. Second anti-oxidation layer; 7. First adhesive layer; 81. Kraft paper; 82. Steel plate; 83. Release film; 84. PP sheet; 85. PI coating film; 9. Dielectric layer; 10. Second adhesive layer; and 10. Limiting part.

### DETAILED DESCRIPTION OF THE EMBODIMENTS

Clear and complete descriptions will be made on technical solutions in the embodiments of the disclosure below in combination with drawings in the embodiments of the disclosure. It is apparent that the described embodiments are a part of embodiments of the disclosure and are not all the embodiments. All other embodiments obtained by those of ordinary skill in the art based on the embodiments in the disclosure without creative work shall fall within the scope of protection of the disclosure.

Referring to FIG. 1, the embodiment of the disclosure provides a metal foil 1. A plurality of protrusions 2 are distributed on one face of the metal foil 1, and the protrusions 2 have the follow microscopic morphology: a lower half part of the protrusion 2 connected with the one face of the metal foil 1 is provided with a limiting part 100, and a diameter of a circumscribed circle of a cross section of the limiting part 100 is smaller than a skin depth of the metal foil 1; and a surface area of the part of the protrusion 2 above the limiting part 100 is larger than a surface area of other parts of the protrusion 2.

Specifically, the skin depth δ is equal to: δ=\sqrt{1/(π*f*σ*μ)}, wherein σ is a conductivity of the material of the protrusion 2 on the metal foil 1, f is a signal frequency in case that the metal foil 1 is used as a signal transmission carrier, and μ is the magnetic permeability.

Herein, the protrusion 2 may be understood as: the part protruding from the surface of the metal foil 1 may be called a protrusion 2. Specifically, the part of the one surface of the metal foil 1 that is raised from other surrounding places is a protrusion 2. The protrusions 2 have a certain distribution on one face of the metal foil 1. The formation manner of the protrusion 2 may be that: the protrusion is formed on the one face of the metal foil 1 by electroplating. Specifically, the protrusion 2 may be formed in the process of manufacturing the metal foil 1. For example, the metal foil 1 is formed by electroplating, and the protrusion 2 is formed by electroplating on the surface of the metal foil 1 in the process of forming the metal foil 1 by electroplating. As another alternative method, the protrusion 2 is not integrally formed with the surface of the one face of the metal foil 1. For example, the formation manner of the protrusion 2 is to form on the one face of the metal foil 1 by sputtering.

Specifically, the protrusion 2 may be formed by a plurality of particle clusters and may also be a single structure. The structural composition of the protrusion 2 is not specifically limited here.

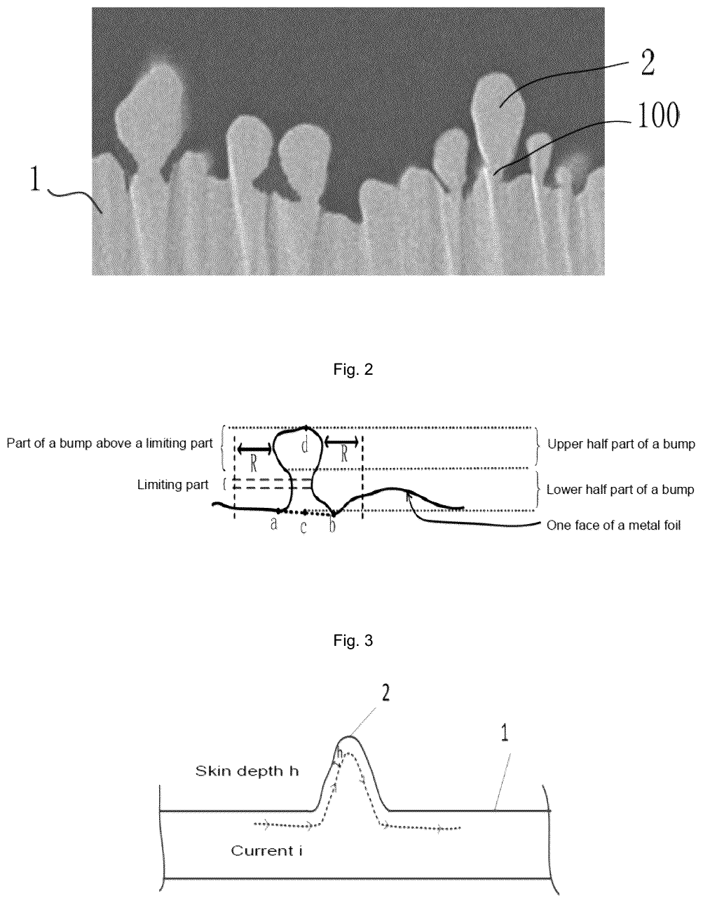

It is to be understood that the lower half part of the protrusion 2 refers to: as shown in FIG. 2, in the height direction of the protrusion 2, with half of the height of the protrusion 2 as the dividing line, the part of the protrusion 2 below the dividing line (the part is close to the one face of the metal foil) is the lower half part of the protrusion 2. Herein, the height of the protrusion 2 may be measured as follows: referring to FIG. 2, in the longitudinal cross-section of the metal foil 1, both sides of the protrusion 2 are within a preset sampling length (which may be set as the maximum diameter R of the diameter of the circumscribed circle of the cross-section of each part of the protrusion 2), and the two sides are at the first lowest point on one face of the metal foil 1 (for example, on the left side of the longitudinal cross-section of the protrusion 2 in FIG. 2, the first lowest point of the side on one face of the metal foil is a; on the right side of the longitudinal section of the protrusion 2, the first lowest point of the side on one face of the metal foil is b), and the midpoint of the two lowest points in the height direction is c, the point c may be regarded as the midpoint of the bottom of the protrusion, and the height of the protrusion 2 is the vertical distance between the highest point d of the protrusion 2 and the midpoint c of the bottom of the protrusion 2. In addition, in FIG. 2, the ab connection line may be regarded as the dividing line between the protrusion 2 and the metal foil 1. It is to be noted that the above description is only a general example.

In addition, it is to be understood that the part where the diameter of the circumscribed circle of the cross section in the lower half part of the protrusion 2 is smaller than the skin depth of the metal foil 1 is the “limiting part” referred to in the disclosure.

The embodiment of the disclosure has at least one aspect of the following beneficial effects: since a plurality of protrusions are distributed on one face of the metal foil, and the protrusions have the following microscopic morphology: the lower half part of the protrusion is provided with a limiting part with the diameter of the circumscribed circle of the cross section smaller than the skin depth; and the surface area of the part of the protrusion above the limiting part is larger than the surface area of other parts of the protrusion. Thus, when the metal foil is manufactured to form a signal transmission line, the limiting part of the protrusion has large impedance, and the narrower the limiting part of the protrusion is, the larger the impedance of the protrusion is. Since the diameter of the circumscribed circle of the cross section of the limiting part of the lower half part of the protrusion is smaller than the skin depth, it is difficult for the high-frequency signal current in the metal foil to pass through the limiting part of the protrusion as limited by the limiting part of the lower half part of the protrusion. Thus, the high-frequency signal current flowing to the protrusion is reduced, enabling the high-frequency signal loss of the signal transmission line formed by manufacture of the metal foil of the embodiments of the disclosure to be less affected by the protrusion on the surface of the metal foil, and reducing the high-frequency signal transmission loss of the signal transmission line formed by manufacture of the metal foil. Furthermore, since the surface area of the part of the protrusion above the limiting part is larger than the surface area of other parts of the protrusion, the surface area of the part of the protrusion above the limiting part is larger than the surface area of the part of the protrusion above the limiting part, so that the protrusion has a relatively large surface area, and thus the signal transmission line formed by manufacture of the metal foil has a large contact area with the dielectric layer. Further, the signal transmission signal and the dielectric layer have good peeling strength, so that both are not easy to fall off in layers, and the high-density and fine-line high-frequency circuit board can be manufactured using the metal foil.

In order to facilitate the understanding of the above description, the following detailed description is made here.

First, a plurality of protrusions 2 are distributed on the one face, and the lower half part of the protrusion 2 has a limiting part with the diameter of the circumscribed circle of the cross section smaller than the skin depth, which limits the high-frequency signal current from flowing to the upper part of the protrusion 2, thus reducing the loss of the protrusion 2 of the metal foil 1 to the high-frequency current, enabling the high-frequency signal loss of the signal transmission line formed by manufacture of the metal foil 1 of the embodiment of the disclosure to be less affected by the protrusion 2 on the surface of the metal foil 1, and reducing the high-frequency signal transmission loss of the signal transmission line formed by manufacture of the metal foil 1.

In addition, the bonding strength between the metal foil 1 with the signal transmission line manufactured and the dielectric layer 9 mainly depends on the physical and chemical adhesion between the interfaces of the metal foil 1 and the dielectric layer 9. Lowering the surface profile of the metal foil 1 means reducing the above-mentioned adhesive ability. The peeling strength (P/S) is used to measure the adhesive strength of a laminate material. Low P/S causes delamination between the metal foil 1 and the dielectric layer 9 of the PCB. Specifically, in the process of manufacturing, assembling and using the PCB, the bonding at the interface between the metal foil 1 with the signal transmission line manufactured and the dielectric layer 9 of the PCB must be very firm. Since the interface is exposed to a corrosive chemical in the process of processing, and exposed to scenarios such as high temperature, high humidity, cold, impact, vibration and shear stress in the process of use, it is necessary to maintain a certain peeling strength between the metal foil 1 and the dielectric layer 9 of the PCB to prevent both from falling off in layer easily.

With regard to the peeling strength between metal foil and the dielectric layer, the conventional art believes that: according to the elasticity theory, referring to Formula 1, factors that affect the high peeling strength between metal foil 1 and the dielectric layer 9 are the thickness y₀ of the metal foil 1 entering dielectric layer 9, the tensile strength σ_{N} of the dielectric layer 9, the thickness δ of the metal foil 1 and the ratio of modulus E of the metal foil 1 to modulus Y of the dielectric layer 9. Herein, according to the conventional art, the thickness of the metal foil 1 entering the dielectric layer 9 may be equal to the height of the side 2 of the metal foil 1 contacting the dielectric layer 9 entering the dielectric layer 9, while the height of the side 2 contacting the dielectric layer 9 entering the dielectric layer 9 is related to the roughness of the one face of the metal foil 1, so the thickness y0 of the metal foil 1 entering the dielectric layer 9 may also be characterized by the roughness of the one face of the metal foil 1. It is to be known from Formula 1 that, in the case where other parametric variables are unchanged, the higher the roughness of the protrusion 2 is, the higher the peeling strength between the metal foil 1 and the dielectric layer 9 is, otherwise the lower the peeling strength between the metal foil 1 and the dielectric layer 9 is.

$$P = 0.38 {{σ}_{N} ( \frac{E}{Y} )}^{1 / 4} {y}_{0}^{1 / 4} {δ}^{1 / 4} . \qquad Formula ( 1 )$$

It is to be seen that the conventional art has the following teaching: on the one hand, the high-density fine-line development trend of the PCB requires that the roughness of a copper foil be as high as possible, so as to improve the peeling strength between the metal foil 1 and the dielectric layer 9. On the other hand, the conventional art has the following contrary teaching: in order to reduce the high-frequency signal transmission loss, the related art requires that the roughness of the metal foil 1 be as small as possible. That is, the two requirements of the conventional art on the surface morphology of the metal foil 1 are mutually contradictory. Herein, the roughness can reflect the contour height of the surface of the metal foil 1. Therefore, in general, according to the existing art, it is considered that in order to reduce the high-frequency signal transmission loss of the metal foil 1, the smaller the contour height of the surface of the metal foil 1 is required; and in order to improve the peeling strength between the high-density signal transmission line and the resin layer on the metal foil 1, the higher the contour height of the surface of the metal foil 1 is required.

However, in the disclosure, creatively, the surface morphology of the metal foil 1 in the high-density fine-line PCB is no longer improved from the angle of the roughness of the metal foil 1, but creatively starts with the structure of the protrusion 2 of the metal foil 1, so that one face of the metal foil 1 is provided with a plurality of protrusions 2, the lower half part of the protrusion connected with the one face is provided with a limiting part, and the diameter of a circumscribed circle of the cross section of the limiting part is smaller than the skin depth of the metal foil; and the surface area of the part of the protrusion above the limiting part is larger than the surface area of other parts of the protrusion. Herein, it is to be understood that “the surface area of the part of the protrusion above the limiting part is larger than the surface area of other parts of the protrusion” as mentioned in the disclosure refers to a structure such as a tree, head and neck or a structure as shown in FIG. 1 or 2 with the upper part generally having a large surface area and the lower part having a small (at least smaller than the upper part) surface area. The part of the whole protrusion 2 contacting with the dielectric layer 9 (such as the resin layer) is mostly the superstructure of the protrusion 2. When the superstructure of the protrusion 2 has a large surface area, correspondingly, the contact area between the protrusion 2 and the dielectric layer 9 is larger. The larger the contact area between the two is, the stronger the bonding force between the two is, that is, the greater the peeling force between the metal foil 1 and the dielectric layer 9 is. Therefore, when the metal foil 1 is provided with a plurality of protrusions 2 described in the disclosure and the protrusions 2 have the above microscopic morphology, the peeling force between the metal foil 1 and the dielectric layer 9 may be significantly improved. That is, the peeling strength between the metal foil 1 and the dielectric layer 9 is large. However, the lower half part of the protrusion 2 is provided with a limiting part with the diameter of the circumscribed circle of the cross section smaller than the skin depth, that is, smaller than the skin depth of the protrusion 2 material. When the high-frequency signal current flows on the surface of the metal foil 1, the impedance at the minimum width is large, so that the high-frequency signal current does not continue to flow to the upper part of the protrusion 2 along the protrusion 2. That is, due to the limitation of the minimum width in the protrusion 2, the high-frequency signal current does not flow to the upper part of the minimum width basically. That is, the high-frequency signal current flowing through the protrusion 2 is limited, thus enabling the high-frequency signal loss of the signal transmission line formed by manufacture of the metal foil 1 of the embodiment of the disclosure to be less affected by the protrusion 2 on the surface of the metal foil 1, and reducing the high-frequency signal transmission loss of the signal transmission line formed by manufacture of the metal foil 1.

Therefore, according to the embodiment of the disclosure, by forming a plurality of the protrusions 2 on the surface of the metal foil 1, the metal foil 1 can give consideration to both the high-frequency signal transmission loss of the metal foil 1 and the peeling strength between the high-density signal transmission line formed by the metal foil 1 and the dielectric layer, thus overcoming the technical prejudice that the contour height of the surface morphology of the metal foil 1 in the conventional art cannot give consideration to both aspects, and starting a new technical innovation of the raw material of the high-density fine-line PCB.

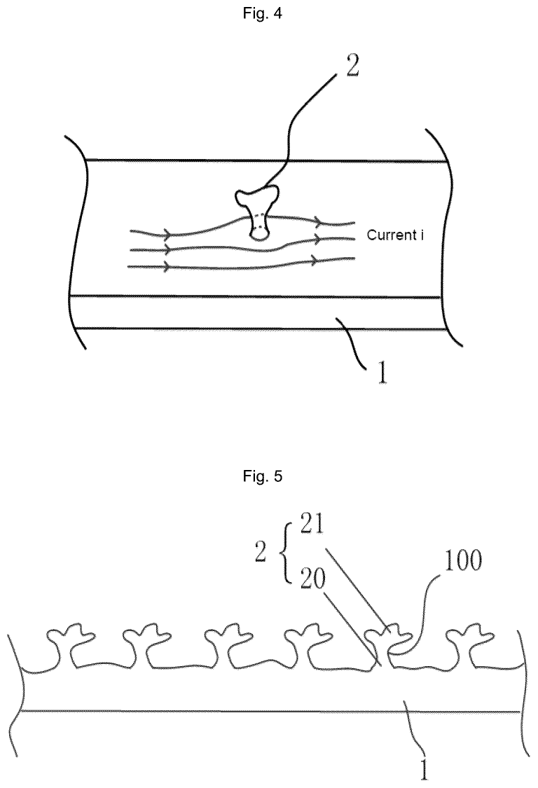

In order to understand that the lower half part of the protrusion 2 is provided a limiting part with the diameter of the circumscribed circle of the cross section smaller than the skin depth, which can greatly reduce the skin effect of the current generated by the protrusion 2 on the one face of the metal foil 1, explanation is made here with reference to FIGS. 3 and 4.

Based on the skin effect of the current, the current of the signal transmission line on the metal foil 1 can only flow on the outer surface of the metal layer with the thickness being the skin depth. As shown in FIG. 3, when the width of the lower half part of the protrusion 2 is greater than the skin depth, the current may flow along the surface of the entire protrusion 2, and the signal transmission loss of the current is greater at this time. However, as shown in FIG. 4, when the width of the lower half part (the root at this time) of the protrusion 2 is smaller than the skin depth, the impedance of the root is larger, the current of the signal transmission line on the metal foil 1 cannot flow on the protrusion 2, but flows on the surface of the signal transmission line to avoid flowing on the protrusion 2, and the protrusion 2 basically does not increase the signal transmission loss of the current in the metal foil 1. In addition, in the embodiment of the disclosure, since the surface area of the part of the protrusion 2 above the limiting part is larger than the surface area of other parts of the protrusion, the contact area between the protrusion 2 and the dielectric layer 9 can be improved, and further the peeling strength between the high-density signal transmission line on the metal foil 1 and the resin layer may be improved.

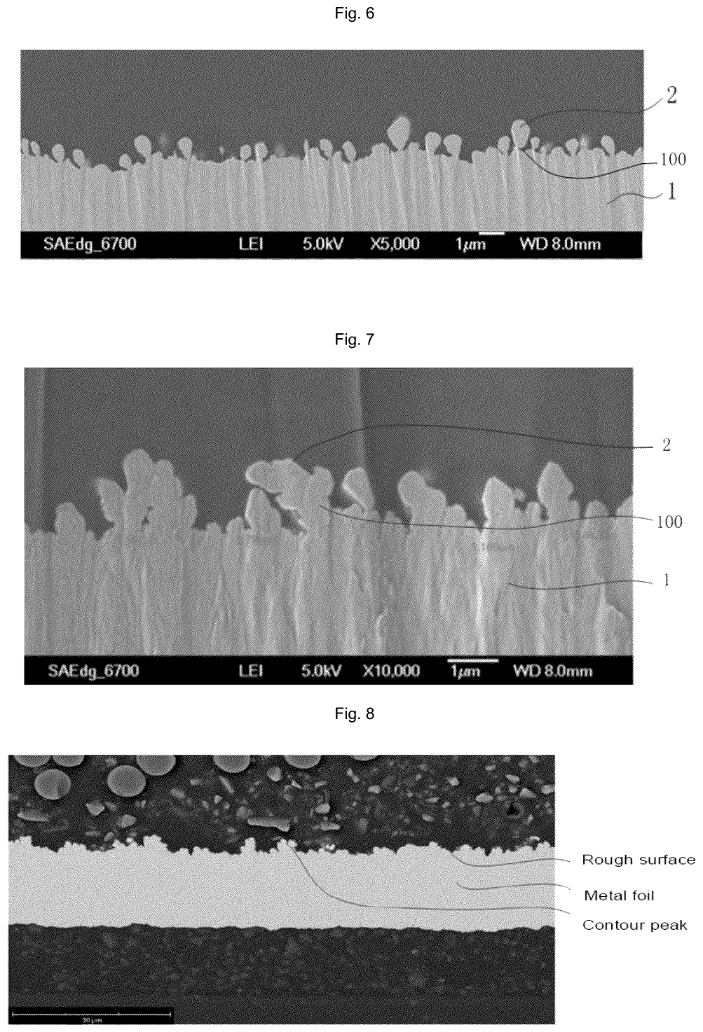

In addition, a further illustration is made here. FIG. 6 is an electron microscope view of a metal foil 1 provided with a plurality of protrusions 2 on one face according to an embodiment of the disclosure. The lower half parts of many protrusions 2 in the plurality of protrusions 2 are each provided with a limiting part 100, and the diameter of the circumscribed circle of the cross section of the limiting part 100 is smaller than the skin depth of the metal foil. It is to be seen from FIG. 6, most of the protrusions 2 in the metal foil 1 are in a narrow-bottom wide-top structure with small width at the bottom and large average width at the upper part, the skin effect of the current of the protrusion 2 on the metal foil 1 is small, and the protrusion 2 also has a large contact area with the dielectric layer 9. FIG. 7 is an electron microscope view of a metal foil 1 provided with a plurality of protrusions 2 on one face according to another embodiment of the disclosure. The lower half parts of many protrusions 2 in the plurality of protrusions 2 are each provided with a limiting part 100, the diameter of the circumscribed circle of the cross section of the limiting part 100 is smaller than the skin depth of the metal foil, and the surface area of the part of the protrusion above the limiting part is greater than the surface area of other parts of the protrusion. Thus, the skin effect of the current of the protrusion 2 on the metal foil 1 is small, and the protrusion 2 also has a large contact area with the dielectric layer 9. FIG. 8 is an electron microscopic view of a conventional metal foil 1. One face of the conventional metal foil is formed as a rough surface, and many contour peaks are formed on the rough surface. The diameter of the circumscribed circle of the cross section of the limiting part of the lower half part of the contour peak is larger than the skin depth, that is, the contour peak is in a wide-bottom narrow-top structure with larger width at the bottom and smaller average width at the upper part, so that the skin effect of the current of the contour peak on the metal foil 1 is large, and it is prone to generating high-frequency signal transmission loss.

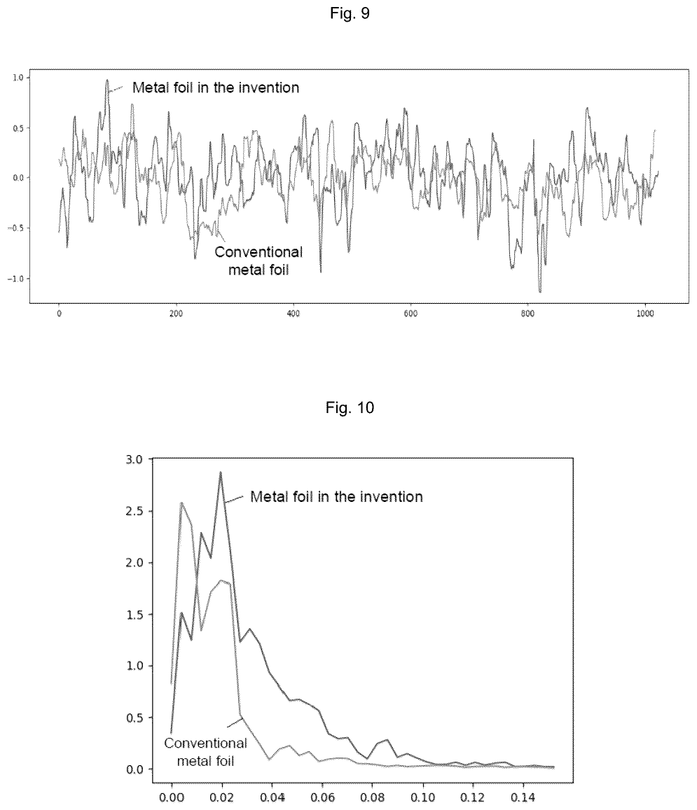

Further reference is made to FIG. 9 and FIG. 10. In actual production, due to the statistical characteristics of metal lattice formed by electrochemistry, the size and shape of the protrusion 2 formed on the surface of the copper foil have a certain distribution. Generally speaking, the shape, size and distribution of the protrusion 2 are determined by the process. FIG. 9 is a scanning curve of slices of one face of two copper foils, used to reflect the morphology contour of the one face of the two copper foil products. One face of the protrusion is scanned from top to bottom by laser. As shown in FIG. 9, there are two curves inside. The upper curve is the contour curve of the face, provided with the protrusion, of the copper foil, and the lower curve is the contour curve of the face, without the protrusion, of the conventional copper foil. It is to be learned from FIG. 9, that the one face of the copper foil in the disclosure has higher protrusion 2 than the one face of the conventional copper foil. It is particularly to be pointed out that the protrusion 2 in the curve is not the real shape of the protrusion 2, as scanned from top to bottom by laser. When the diameter of the root of the protrusion 2 is smaller than the diameter of the upper part of the protrusion, the shape of the root of the protrusion cannot be obtained by the measurement. However, the size distribution of the diameter of the protrusion 2 can be quickly determined by the measurement, providing an effective method for comparison of different processes for forming the protrusion 2 and optimization thereof. Fourier spectral analysis is one of the most efficient methods to analyze the size of microscopic protrusions 2 on the surface of the metal foil 1 and to count the distribution of the protrusions 2. FIG. 10 is a logarithmic spectrum diagram of corresponding spatial Fourier transform of a curve in FIG. 9. There are two frequency spectrum curves in the logarithmic spectrum diagram. The lower frequency spectrum curve represents the frequency spectrum curve of the above-mentioned conventional copper foil, and the upper frequency spectrum curve represents the frequency spectrum curve of the copper foil with a plurality of the protrusions 2 provided on one face according to the embodiment of the present application. The spectrum curve is obtained by Fourier transformation on topographical test data of the surfaces of the two copper foils. The abscissa in the logarithmic spectrum diagram is the normalized spatial frequency data, and the ordinate in the logarithmic spectrum diagram is the spectral intensity in log-form after a log calculation (20 log A) on an original amplitude, so that the unit of the ordinate is dB (decibels). This transformation aims to make those components with lower amplitudes higher than those with higher amplitudes, so as to observe a periodic signal masked by low-amplitude noise.

From FIGS. 9 and 10, it is apparent that the protrusions on one face of the copper foil of the disclosure as shown in the figure are different from the protrusions on one face of the conventional copper foil in size and distribution. It is to be noted that the conventional copper foil mentioned above is not an existing copper foil product, but is used in the disclosure as a comparative example of the copper foil of the disclosure.

As an example, a height of the limiting part with respect to the one face of the metal foil may be not more than 2 microns (for example, less than 1.5 microns, 1.2 microns, 1 micron, 0.8 micron, 0.5 micron, etc.), so that the skin effect of the current flowing on the metal foil on the protrusion is relatively weak, and a relatively high high-frequency signal transmission loss can be more effectively avoided from being easily generated due to large skin effect of the current of the protrusion 2 on the metal foil 1.

As an example, a height of the protrusion 2 is not particularly limited, and may be not more than 3 microns, for example. Thus, in the case where the protrusion 2 has the above-mentioned microscopic morphology of the disclosure, when the protrusion 2 has the above-mentioned height, the peeling strength of the metal foil 1 may be further increased, so that the metal foil 1 is more suitable for high-density fine-line high-frequency circuit boards.

Exemplarily, a ratio of a longitudinal length of the part of the protrusion above the limiting part to a height of the protrusion is: 1/2-5/6. Thus, the part of the protrusion above the limiting part is relatively longer in the entire protrusion, so that the surface of the part of the protrusion above the limiting part is increased with respect to the surface of the remaining part of the protrusion, the surface area of the upper part of the protrusion is relatively increased, there is a relatively large contact area between the signal transmission line formed by the manufacture of the metal foil and the dielectric layer, and then there is a good peel strength between the signal transmission signal and the dielectric layer to enable the two to not easily fall off in layers.

Exemplarily, a shape of the protrusion 2 is not particularly limited, and may for example, be tree-shaped, hung-ice-shaped or water-drop-shaped. Furthermore, when the protrusion 2 is tree-shaped, hung-ice-shaped or water-drop-shaped, the specific structure of the wider upper part is not particularly limited, which may be selected by those skilled in the art according to the actual needs. It is found by an inventor that when the protrusion 2 is tree-shaped, hung-ice-shaped or water-drop-shaped, not only the protrusion 2 can have low high-frequency signal transmission loss, but also it is possible for the protrusion 2 and the dielectric layer 9 to have large surface area since the upper part of the tree-shaped, hung-ice-shaped or water-drop-shaped protrusion 2 has relatively large surface area, thus facilitating improving the bonding force between the metal foil 1 and the dielectric 9. That is, the peeling strength between the metal foil 1 and the dielectric layer 9 is enabled to be large, meeting the requirement of a high-density fine-line high-frequency circuit board. Furthermore, the protrusion 2 may also be tooth-shaped, as long as the protrusion 2 has the above microscopic morphology. The shape and structure of the protrusion 2 are not specifically limited here.

As an example, the metal foil 1 includes a copper foil and/or an aluminum foil. That is, the metal foil 1 may be the copper foil or the aluminum foil, may also include the copper foil and the aluminum foil (equivalent to the metal foil 1 formed by laminating a copper foil layer and an aluminum foil layer), or may also be a layer of metal foil 1 including both copper and aluminum.

As an example, the metal foil 1 may be a single-layer structure and may also be a multi-layer structure composed of at least two single metal layers.

As an example, the thickness of the metal foil 1 is smaller than or equal to 9 μm. In order to meet the requirements of manufacturing a fine signal transmission line of a circuit board, preferably, the thickness of the metal foil 1 may be 6 μm, 5 μm, 4 μm or 2 μm, so as to obtain the extremely thin metal foil 1 which facilitates forming the fine signal transmission line.

In order to verify that compared with the conventional art, the metal foil 1 provided by the embodiment of the disclosure can not only reduce the high-frequency signal transmission loss of the metal foil 1, but also enable the signal transmission line formed by manufacture of the metal foil 1 to have good peeling strength with the resin layer, so that the two are not easy to fall off in layers. Taking the metal foil 1 being the copper foil as an example, an inventor provides the following test samples.

Herein, the test sample 1 is the copper foil in the disclosure, and the test sample 2 is a conventional copper foil as a comparative sample of the disclosure. The conventional copper foil refers to a product without the protrusion 2 in the disclosure and the microscopic morphology thereof.

Test sample 1: a plurality of protrusions 2 are distributed on one face of the metal foil, and more than ⅓ of the protrusions 2 have the following microscopic morphology when the frequency is 1 Ghz: the lower half part of the protrusion connected with the one face is provided with a limiting part, and the diameter of a circumscribed circle of the cross section of the limiting part is smaller than the skin depth of the metal foil; and the surface area of the part of the protrusion above the limiting part is larger than the surface area of other parts of the protrusion. Herein, the skin depth δ is equal to: δ=\sqrt{1/(π*f*σ*μ)}, where σ is the conductivity of the material of the protrusion 2 on the metal foil 1, f is the signal frequency when the metal foil 1 is used as a signal transmission carrier, and u is the magnetic permeability.

Taking the dielectric layer 9 being a resin layer as an example (the same is true for the following test example), after testing, the peeling strength between the one face of the copper foil and the resin layer is 10 N/cm, and the transmission loss of the high-frequency signal of the copper foil is shown in Table 1.

In addition, the test method of the peeling strength between the one face of the copper foil and the resin layer is as follows.

The test method is a test method of thermal stress peel strength, which is used to test the peeling strength of metal cladding after thermal shock and evaluate the deterioration of the peeling strength of a copper foil sample after thermal shock. The details are as follows (the test standard of the test method may refer to the standard IPC-TM-650 2. 4. 8).

### (1) Sample Preparation Stage:

1. Pressing parameters: press pressing, pressing size of 120×180 mm, quantity of 1 pcs;
2. Pressing auxiliary materials: kraft paper 81, a steel plate 82, a release film 83, a PP sheet 84, and a PI covering film 85.

### (2) Test Operation Stage:

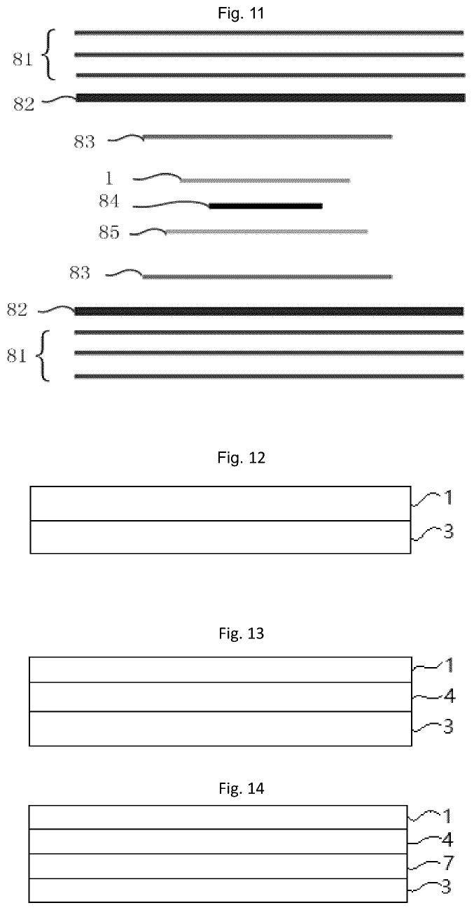

1. As shown in FIG. 11, pressing is performed in a laminated mode of copper foil/PP sheet 84/PI covering film 85;
2. Whether to perform electroplating thickening treatment is judged according to requirements, and baking is performed for 90 min in a 160° C. oven after electroplating;
3. Floating tin is performed in a 288° C. solder bath for 10 s;
4. A 5 mm wide test bar is drawn with an art knife;
5. A PI surface is applied to a roller of a peeling strength tester, and thin copper of about 2 cm is peeled and clamped on a chuck; and
6. Stretch is performed upward vertically, 6 groups of stable peeling strength data are respectively recorded, and a mean value of the 6 peeling strength data is calculated and recorded as F (N/cm).

Herein, the pressing condition is that: the metal foil 1 is pressed using a press, and the pressing parameters are as follows.
1) The pressure in a heating section (<90° C.) is maintained at 8 kgf/cm², and the heating rate is ˜3.5° C./min.
2) Turning to high pressure at 90° C., the pressure is maintained at 30 kgf/cm², and the heating rate is ˜4.5° C./min.
3) The pressure in a high-temperature section (200° C.) is maintained at 30 kgf/cm² for 2 h.
4) Cooling down to ˜50° C., the sample is taken under pressure relief.

It is to be noted that: the pressure refers to the surface pressure, indicating the pressure applied per unit area.

The test method for the transmission loss of the high-frequency signal of the copper foil is as follows.

Conventional double panels are laminated, and the signal line is a 50 ohm microstrip line. The dielectric layer is a 25 micron polyimide.

The pressing parameters are: pressing size of 200×250 mm, quantity of 1 pcs, and 185° C.*3 min*120 kg/cm².

The pressing auxiliary materials are: kraft paper 81, a steel plate 82, TPX, PET, prepreg and Jiang copper.
1. Pressing is performed in a laminated mode of copper foil/prepreg/hard plate/prepreg/Jiang copper.
2. Electroplating is performed to thicken to 20 microns and baking is performed in a 160° C. oven for 30 min prior to testing.

Herein, the pressing condition is that: the metal foil 1 is pressed using a press, and the pressing parameters are as follows.
1) The pressure in a heating section (<90° C.) is maintained at 8 kgf/cm², and the heating rate is ˜ 3.5° C./min.
2) Turning to high pressure at 90° C., the pressure is maintained at 30 kgf/cm², and the heating rate is ˜ 4.5° C./min.
3) The pressure in a high-temperature section (200° C.) is maintained at 30 kgf/cm² for 2 h.
4) Cooling down to ˜ 50° C., the sample is taken under pressure relief.

It is to be noted that: the pressure refers to the surface pressure, indicating the pressure applied per unit area.
3. The baked sample is cut and attached to a thermosetting plate to obtain a test plate.
4. The test plate is welded and then tested using a network analyzer.

It is to be understood that the following test method for the peeling strength between the copper foil and the resin layer and the test method for the transmission loss of a high-frequency signal of the copper foil in the following test example may refer to the relevant description of the test example 1.

### Test Sample 2

A conventional sample is tested. The copper foil described in the disclosure in the test sample 1 is replaced with a conventional copper foil (a conventional copper foil without the protrusion 2 and the microscopic morphology thereof described in the disclosure), and the other test condition is consistent with the test sample 1.

After testing, the peeling strength between the conventional copper foil and the resin layer is 4 N/cm, and the transmission loss of the high-frequency signal of the conventional copper foil is shown in Table 1.

TABLE 1
Comparison of high-frequency signal transmission loss between
a copper foil in the disclosure and a conventional copper foil

| | Conventional | Copper foil in |
|---|---|---|
| Frequency | copper foil | the disclosure |
| (Ghz) | (dB) | (dB) |
| 1.0 | −2.23 | −1.52 |
| 2.0 | −4.31 | −2.46 |
| 3.0 | −7.53 | −4.82 |
| 5.0 | −10.95 | −6.77 |
| 7.0 | −14.35 | −8.32 |
| 9.0 | −19.29 | −11.19 |
| 10 | −24.18 | −15.54 |

It is to be learned from the above-mentioned test that the copper foil in the disclosure has a lower high-frequency signal transmission loss and higher peeling strength between the copper foil and the dielectric layer than the conventional copper foil, namely, the copper foil having the structure of the protrusion 2 in the disclosure in comparison with the conventional copper foil without the protrusion 2 in the disclosure and the microscopic morphology thereof, and has a significant advantage when used for manufacturing a high-density fine-line high-frequency circuit board.

In the above-mentioned embodiment, as an example, referring to FIG. 5, the protrusion 2 includes a trunk part 20 and a branch part 21. The trunk part 20 extends outward from the one face, and the branch part 21 extends outward from the surface of the trunk part 20. Thus, during the high-frequency signal current transmission, the current flows along the metal surface, and it is difficult for the current to continue to flow up the trunk part 20 to the branch part 21 due to the limit by the limiting part of the trunk part 20, thereby enabling the loss of transmission of the high-frequency signal current of the metal foil 1 by the protrusion 2 to be extremely limited. In addition, the branch part 21 extending outward from the surface of the trunk part 20 can increase the bonding area between the signal transmission line formed by manufacture of the metal foil 1 and the dielectric layer, and further improve the bonding force between the signal transmission line formed by manufacture of the metal foil 1 and the dielectric layer, so that the signal transmission line formed by manufacture of the metal foil 1 and the dielectric layer can further have good peeling strength there between, thus being not easy to fall off in layers, and a high-density and fine-line high-frequency circuit board can be further manufactured using the metal foil 1. It is to be noted that the number and shape of the branch parts 21 on the trunk part 20 are not particularly limited, and those skilled in the art may make a selection according to actual needs.

Further, the material composition of the trunk part 20 may be the same as the metal foil and may also be different from the metal foil 1. For example, when the metal foil 1 is a copper foil or an aluminum foil or contains copper and aluminum, the material composition of the trunk part 20 may be at least one of copper, nickel, zinc, chromium, aluminum, silicon, alumina particles and industrial diamond particles. Thus, there are more possibilities for forming the protrusion 2, the trunk part 20 or the branch part 21, and also more design possibilities for the protrusion 2, the trunk part 20 or the branch part 21. Herein, the industrial diamond particles are micron-sized industrial diamond particles.

As an example, on the one face, the percentage of the protrusions 2 having the microscopic morphology in the metal foil 1 is not particularly limited, which, for example, may be that at least 10% of the protrusions 2 have the microscopic morphology, preferably at least 50% of the protrusions 2 have the microscopic morphology, further preferably at least 10% of the protrusions 2 have the microscopic morphology. It is found by an inventor that, on the one face, the larger the ratio of the protrusions 2 having the microscopic morphology in the metal foil 1 is, the lower the high-frequency signal transmission loss is and the higher the peeling strength with the dielectric layer is due to the protrusions 2, and the more suitable for products high requiring high-frequency signal transmission loss and peeling strength.

As an example, the specific value of the signal frequency f when the metal foil 1 is used as a signal transmission carrier is not particularly limited, which may be determined according to the actual use environment of the product, and may for example, be 1 Hz-100 GHz.

Referring to FIG. 12, another embodiment of the disclosure provides a metal foil 1 with a carrier, which includes a carrier layer 3 and a metal foil 1 described in any of the abovementioned solutions. The carrier layer 3 is arranged on the face, provided with the protrusion 2, of the metal foil 1 in a peelable manner.

Referring to FIG. 13, specifically, the metal foil 1 with a carrier also includes a peeling layer 4. The peeling layer 4 is located between the carrier layer 3 and the metal foil 1, so that both the metal foil 1 and the carrier layer 3 are arranged in a peelable manner.

It is to be understood that when the carrier layer 3, the peeling layer 4 and the metal foil 1 are sequentially laminated, the peeling strength between the metal foil 1 and the peeling layer 4 is greater than the peeling strength between the peeling layer 4 and the carrier layer 3, so that the carrier layer 3 can be smoothly peeled from the metal foil 1.

It is to be noted that the carrier layer 3 is a carrier substrate for the metal foil 1. The function of the peeling layer 4 is: to reduce the mutual penetration of the carrier layer 3 and the metal foil 1 on the one hand and to facilitate the peeling between the carrier layer 3 and the metal foil 1 on the other hand.

According to the embodiment of the disclosure, the abovementioned metal foil 1 is applied, so that not only can the high-frequency signal transmission loss of the metal foil 1 be reduced, but also a signal transmission line formed by manufacture of the metal foil 1 and a resin layer are enabled to have good peeling strength, making the two not easy to fall off in layers. Thus, the manufacture of a high-density and fine-line high-frequency circuit board with the metal foil 1 can be implemented.

As an example, the peeling layer 4 is made of any one or more of nickel, silicon, molybdenum, graphite, titanium and niobium. Or, the peeling layer 4 is made of an organic polymer material. Herein, the thickness of the peeling layer 4 is preferably 10-500 A. Since it is difficult to form a uniform metal foil 1 when the peeling layer 4 is too thick, a large number of pinholes are easily formed in the metal foil 1 (when the metal foil 1 has pinholes thereon, an open circuit phenomenon will easily occur after same is etched into a line). When the peeling layer 4 is too thin, same is difficult to be peeled from the metal foil 1. Therefore, the thickness of the peeling layer 4 is preferably between 10 and 500 A, thus ensuring that a uniform metal foil 1 can be formed, avoiding the formation of a large number of pinholes in the metal foil 1, and enabling easy peeling between the peeling layer 4 and the metal foil 1.

In addition, the carrier layer 3 may be carrier copper, carrier aluminium or an organic thin film, etc. Since the carrier layer 3 mainly plays a supporting role, a certain thickness is required. When the carrier layer 3 is carrier copper or carrier aluminium, the thickness of the carrier layer 3 is preferably 9-50 μm. When the carrier layer 3 is an organic thin film, the thickness of the carrier layer 3 is preferably 10-100 μm.

Referring to FIG. 14, in the abovementioned embodiment, furthermore, the metal foil 1 with a carrier also includes a first adhesive layer 7, and the first adhesive layer 7 is arranged between the carrier layer 3 and the peeling layer 4.

In the present embodiment, the first adhesive layer 7 is provided, so that the first adhesive layer 7 not only enables the peeling strength between the peeling layer 4 and the carrier layer 3 to be strong, effectively ensuring that the carrier layer 3 can be stably peeled off from the metal foil 1, and then obtaining a complete extremely thin metal foil 1, but also enables the surface of the carrier layer 3 to be treated with the first adhesive layer 7, so that the whole surface of the carrier layer 3 is more uniform and dense, thereby facilitating the peeling from the carrier layer 3 to obtain the extremely thin metal foil 1 with less pinholes, and then facilitating the manufacture of a subsequent circuit.

Specifically, the first adhesive layer 7 is a metal adhesive layer. Exemplarily, the metal adhesive layer is made of any one or more materials of copper, zinc, nickel, iron and manganese or, the first metal adhesive layer is made of one of copper and zinc and one of nickel, iron and manganese.

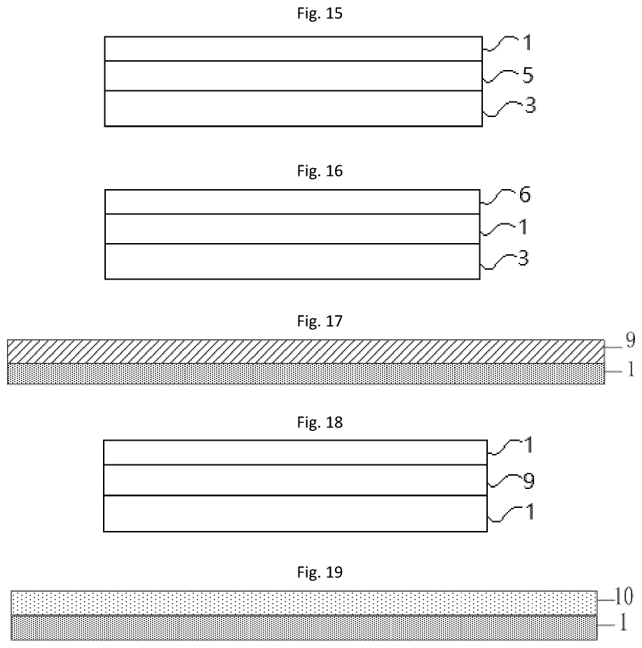

Referring to FIG. 15, in the embodiment of the disclosure, in order to prevent oxidation of the carrier layer 3, a first anti-oxidation layer 5 is arranged on the side of the carrier layer 3 close to the metal foil 1 in the embodiment. The first anti-oxidation layer 5 is arranged on the side of the carrier layer 3 close to the metal foil 1, so as to prevent the carrier layer 3 from oxidation and then protect the carrier layer 3. Referring to FIG. 16, in order to prevent the metal foil 1 from oxidization, a second anti-oxidation layer 6 is arranged on the side of the metal foil 1 away from the carrier layer 3. The second anti-oxidation layer 6 is arranged on the side of the metal foil 1 away from the carrier layer 3, so as to prevent the metal foil 3 from oxidation and then protect the metal foil 1.

Specifically, the material of the first anti-oxidation layer 5 is at least one of nickel, copper alloy and chromium.

Specifically, the second anti-oxidation layer 6 contains nickel and zinc.

Another embodiment of the disclosure provides a copper-clad laminate, which is obtained using the metal foil 1 described in any of the abovementioned solutions or the metal foil 1 with a carrier described in any of the abovementioned solutions.

Exemplarily, referring to FIGS. 17-18, the copper-clad laminate further includes a dielectric layer, and the dielectric layer is arranged on the one face of at least one metal foil. Specifically, the material of the dielectric layer is selected from at least one of polyimide (for example thermoplastic polyimide), modified epoxy resin, modified acrylic resin, polyethylene terephthalate, polybutylene terephthalate, polyethylene, polyethylene naphthalate, polystyrene, polyvinyl chloride, polysulfone, polyphenylene sulfide, polyetheretherketone, polyphenylene ether, polytetrafluoroethylene, liquid crystal polymer, polyparabanic acid, epoxy glass cloth and BT resin.

Furthermore, referring to FIG. 19, the copper-clad laminate further includes a second adhesive layer, and the second adhesive layer is arranged on the one face of the metal foil. Specifically, the material of the second adhesive layer is selected from at least one of polystyrene, vinyl acetate, polyester, polyethylene, polyamide, rubber or acrylate thermoplastic resin, phenolic, epoxy, thermoplastic polyimide, carbamate, melamine or alkyd thermosetting resin, BT resin and ABF resin.

Another embodiment of the disclosure provides a PCB (not shown in the figure), which is obtained using the metal foil 1 described in any of the abovementioned solutions, the metal foil 1 with a carrier described in any of the abovementioned solutions, or the copper-clad laminate described in any of the abovementioned solutions.

The above is the optional implementation mode of the disclosure. It is to be pointed out that those of ordinary skill in the art may further make a plurality of improvements and replacements without departing from the principle of the disclosure, and these improvements and replacements shall also fall within the scope of protection of the disclosure.

What is claimed is:

1. A metal foil for a circuit board, wherein a plurality of protrusions are distributed on one face of the metal foil, the protrusions having the following microscopic morphology:
a lower half part of the protrusion connected with the one face of the metal foil being provided with a limiting part, and a diameter of a circumscribed circle of a cross section of the limiting part being smaller than a skin depth of the metal foil; and a surface area of the part of the protrusion above the limiting part being larger than a surface area of other parts of the protrusion.

2. The metal foil for the circuit board as claimed in claim 1, wherein the skin depth δ is equal to: δ=\sqrt{1/(π*f*σ*μ)}, wherein, is a conductivity of the material of the protrusion, f is a signal frequency in a case that the metal foil is used as a signal transmission carrier, and μ is the magnetic permeability.

3. The metal foil for the circuit board as claimed in claim 1, wherein a height of the limiting part relative to the one face of the metal foil is not more than 2 microns, a height of the protrusion relative to the one face of the metal foil is not more than 4 microns; or
a ratio of a longitudinal length of the part of the protrusion above the limiting part to a height of the protrusion is: 1/2-5/6; or
a shape of the protrusion is tree-shaped, hung-ice-shaped or water-drop-shaped; or
on the one face, at least 10% of the protrusions have the microscopic morphology; or
on the one face, at least 50% of the protrusions have the microscopic morphology; or
on the one face, at least 90% of the protrusions have the microscopic morphology; or
the metal foil comprises a copper foil and/or an aluminum foil; or
the metal foil is a single-layer metal structure or a multi-layer metal structure composed of at least two single metal layers.

4. The metal foil for the circuit board as claimed in claim 1, wherein a ratio of a longitudinal length of the part of the protrusion above the limiting part to a height of the protrusion is: 1/2-5/6.

5. The metal foil for the circuit board as claimed in claim 1, wherein a shape of the protrusion is tree-shaped, hung-ice-shaped or water-drop-shaped.

6. The metal foil for the circuit board as claimed in claim 1, wherein the protrusion comprises a trunk part and a branch part, the trunk part extend outward from the one face, the trunk part is provided with the limiting part, and the branch part extend outward from a surface of a part of the trunk part above the limiting part.

7. The metal foil for the circuit board as claimed in claim 6, wherein a material composition of the trunk part is the same as a material composition of the metal foil, or
a material composition of the trunk part is different from a material composition of the metal foil, the material of the trunk part is selected from at least one of copper, nickel, zinc, chromium, aluminum, silicon, alumina particles and industrial diamond particles.

8. (canceled)

9. (canceled)

10. The metal foil for the circuit board as claimed in claim 2, wherein the signal frequency f is:
1 Hz-100 GHz.

11. (canceled)

12. (canceled)

13. A metal foil with a carrier, comprising a carrier layer and the metal foil for the circuit board as claimed in claim 1, wherein the carrier layer is arranged on another face, opposite to the one face, of the metal foil in a peelable manner.

14. The metal foil with the carrier as claimed in claim 13, wherein, the metal foil with the carrier also comprises a peeling layer, the peeling layer is located between the carrier layer and the metal foil, so that both the metal foil and the carrier layer are arranged in a peelable manner.

15. The metal foil with the carrier as claimed in claim 14, wherein the metal foil with the carrier also comprises a first adhesive layer, the first adhesive layer being arranged between the carrier layer and the peeling layer.

16. The metal foil with the carrier as claimed in claim 15, wherein, the first adhesive layer is a metal adhesive layer, the metal adhesive layer is made of any one or more materials of copper, zinc, nickel, iron and manganese or, the metal adhesive layer is made of one of copper and zinc and one of nickel, iron and manganese.

17. The metal foil with the carrier as claimed in claim 13, wherein, the metal foil with the carrier also comprises a first anti-oxidation layer, the first anti-oxidation layer is arranged on a face of the metal foil close to the carrier layer.

18. The metal foil with the carrier as claimed in claim 17, wherein a material of the first anti-oxidation layer is at least one of nickel, chromium and copper alloy.

19. The metal foil with the carrier as claimed in claim 13, wherein, the metal foil with the carrier also comprises a second anti-oxidation layer, the second anti-oxidation layer is arranged on a face of the metal foil away from the carrier layer.

20. The metal foil with the carrier as claimed in claim 19, wherein a material of the second anti-oxidation layer is at least one of nickel, chromium and zinc.

21. A copper-clad laminate, comprising the metal foil as claimed in claim 1.

22. The copper-clad laminate as claimed in claim 21, wherein, the copper-clad laminate further comprises a dielectric layer, the dielectric layer is arranged on the one face of at least one metal foil.

23. The copper-clad laminate as claimed in claim 22, wherein a material of the dielectric layer is selected from at least one of polyimide, modified epoxy resin, modified acrylic resin, polyethylene terephthalate, polybutylene terephthalate, polyethylene, polyethylene naphthalate, polystyrene, polyvinyl chloride, polysulfone, polyphenylene sulfide, polyetheretherketone, polyphenylene ether, polytetrafluoroethylene, liquid crystal polymer, polyparabanic acid, epoxy glass cloth and BT resin.

24. The copper-clad laminate as claimed in claim 21, wherein, the copper-clad laminate further comprises a second adhesive layer, the second adhesive layer is arranged on the one face of the metal foil.

25. The copper-clad laminate as claimed in claim 24, wherein a material of the second adhesive layer is selected from at least one of polystyrene, vinyl acetate, polyester, polyethylene, polyamide, rubber or acrylate thermoplastic resin, phenolic, epoxy, thermoplastic polyimide, carbamate, melamine or alkyd thermosetting resin, BT resin and ABF resin.

26. A Printed Circuit Board (PCB), being obtained using the metal foil for the circuit board as claimed in claim 1.
